(19) United States
(12) Patent Application Publication
(10) Pub. No.: US 2026/0135550 A1
(43) Pub. Date: May 14, 2026

(54) LEVEL SHIFTER

(71) Applicant: eMemory Technology Inc., Hsin-Chu (TW)

(72) Inventors: Chih-Yang Huang, Hsinchu County (TW); Wei-Chiang Ong, Hsinchu County (TW); Wei-Ming Ku, Hsinchu County (TW); Cheng-Yu Chung, Hsinchu County (TW); Chih-Hao Huang, Hsinchu County (TW)

(21) Appl. No.: 19/377,094

(22) Filed: Nov. 3, 2025

Related U.S. Application Data
(60) Provisional application No. 63/719,167, filed on Nov. 12, 2024.

(51) Int. Cl. H03K 17/041; H03K 19/013; H03K 19/17784

(52) U.S. Cl. CPC H03K 17/04106; H03K 19/0136; H03K 19/17784

(57) ABSTRACT

A level shifter includes a cross-coupled circuit, a differential pair circuit, a NOT gate and a pulling device. The NOT gate receives an input signal and generates an inverted input signal. The cross-coupled circuit is connected to a first node and a second node. The cross-coupled circuit receives a first supply voltage. The voltage at the second node is used as an output signal. The differential pair circuit is connected to the first node and the second node. The differential pair circuit receives a ground voltage, the input signal and the inverted input signal. The pulling device is connected to the second node. The pulling device receives an enable signal. When the enable signal is not activated, the output signal is maintained at a specified logic level. When the enable signal is activated, the output signal changes with a change of the input signal.

This application claims the benefit of U.S. provisional application Ser. No. 63/719,167, filed Nov. 12, 2024, the subject matters of which is incorporated herein by reference.

### FIELD OF THE INVENTION

The present invention relates to a circuit, and more particularly to a level shifter.

### BACKGROUND OF THE INVENTION

Generally, an integrated circuit (IC) has different power domains. The circuits in different power domains receive different supply voltages. For example, the supply voltage of the V_{DD1} power domain is V_{DD1}, and the supply voltage of the V_{DD2} power domain is V_{DD2}. The supply voltage V_{DD1} and the supply voltage V_{DD2} are different from each other. For example, the supply voltage V_{DD1} is 1.2V, and the supply voltage V_{DD2} is 5V.

Nowadays, the CMOS semiconductor manufacturing process is selected according to the operating voltage range of the semiconductor device. For example, the CMOS manufacturing process for a medium voltage device (also referred as a MV device) is used to fabricate a transistor that withstands higher voltage stress, and this transistor is suitable for the medium voltage operation. In addition, the CMOS manufacturing process for a low voltage device (also referred as a LV device) is used to fabricate a transistor that has the fast computing speed and withstands the lower voltage stress, and this transistor is suitable for the low voltage operation. For example, in the medium voltage operation, the voltage stress that can be withstood by the region between the gate terminal and the source terminal of the transistor is in the range between 3.0V and 10V. Moreover, in the low voltage operation, the voltage stress that can be withstood by the region between the gate terminal and the source terminal of the transistor is in the range between 0.8V and 2.0V.

FIG. 1A is a schematic circuit diagram illustrating the operations of the circuits between different power domains in an IC chip. In the V_{DD1} power domain of the IC chip 100, the logic high level of the signal operated by a first circuit 102 is the supply voltage V_{DD1}, and the logic low level is a ground voltage GND. In the V_{DD2} power domain of the IC chip 100, the logic high level of the signal operated by a second circuit 106 is the supply voltage V_{DD2}, and the logic low level is the ground voltage GND.

Furthermore, a level shifter 104 is used to convert logic levels of the signals between different power domains. Consequently, the circuits in different power domains can communicate with each other normally. Generally, the main circuit of the IC chip (i.e., the second circuit 106) is included in the V_{DD2} power domain, and only few circuits (e.g., the first circuit 102) are included in the V_{DD1} power domain.

For example, the first circuit 102 uses a control signal C_{TRL1} to communicate with the second circuit 106. Meanwhile, the level shifter 104 receives the control signal C_{TRL1} from the first circuit 102 as an input signal IN of the level shifter 104. In addition, an output signal OUT generated by the level shifter 104 is served as another control signal C_{TRLA}. The control signal C_{TRLA} is transmitted to the second circuit 106. That is, by the level shifter 104, the control signal C_{TRL1} with the logic high level (i.e., V_{DD1}) in the V_{DD1} power domain is converted into the control signal C_{TRLA} with the logic high level (i.e., V_{DD2}) in the V_{DD2} power domain. In addition, by the level shifter 104, the control signal C_{TRL1} with the logic low level (i.e., GND) in the V_{DD1} power domain is converted into the control signal C_{TRLA} with the logic low level (i.e., GND) in the V_{DD2} power domain. Consequently, the two circuits 102 and 106 can communicate with each other normally.

In case that the first circuit 102 uses more control signals to communicate with the second circuit 106, more level shifters are needed. For example, if the first circuit 102 uses ten control signals to communicate with the second circuit 106, ten level shifters are required to convert the logic levels of the ten control signals.

FIG. 1B is a schematic circuit diagram of a conventional level shifter. By the level shifter 110, an input signal IN and an inverted input signal ZIN in the range between the supply voltage V_{DD1} and the ground voltage GND are converted into an output signal OUT in the range between the supply voltage V_{DD2} and the ground voltage GND. For example, the supply voltage V_{DD1} is 1.2V, the supply voltage V_{DD2} is 5V, and the ground voltage GND is 0V. That is, the supply voltage V_{DD2} is higher than the supply voltage V_{DD1}, and the supply voltage V_{DD1} is higher than the ground voltage GND.

As shown in FIG. 1B, the level shifter 110 includes a NOT gate 116, a cross-coupled circuit 112 and a differential pair circuit 114. The NOT gate 116 is included in the V_{DD1} power domain, and the cross-coupled circuit 112 and the differential pair circuit 114 are included in the V_{DD2} power domain. The cross-coupled circuit 112 includes a P-type transistor M_{P1} and a P-type transistor M_{P2}. The differential pair circuit 114 includes an N-type transistor M_{N1} and an N-type transistor M_{N2}. The P-type transistor M_{P1}, the P-type transistor M_{P2}, the N-type transistor M_{N1} and the N-type transistor M_{N2} are all MOSFET transistors.

The two power terminals of the NOT gate 116 are respectively connected to the supply voltage V_{DD1} and the ground voltage GND. The input terminal of the NOT gate 116 receives the input signal IN. The output terminal of the NOT gate 116 generates the inverted input signal ZIN. The input signal IN and the inverted input signal ZIN are complementary to each other.

The cross-coupled circuit 112 is connected to the node a and the node b. In addition, the cross-coupled circuit 112 receives the supply voltage V_{DD2}. The source terminal of the P-type transistor M_{P1} receives the supply voltage V_{DD2}. The drain terminal of the P-type transistor M_{P1} is connected to the node a. The gate terminal of the P-type transistor M_{P1} is connected to the node b. The source terminal of P-type transistor M_{P2} receives the supply voltage V_{DD2}. The drain terminal of P-type transistor MP₂ is connected to the node b. The gate terminal of P-type transistor MP₂ is connected to the node a. The voltage at the node b is the output signal OUT.

The differential pair circuit 114 is connected to the node a and the node b. In addition, the differential pair circuit 114 receives the ground voltage GND, the input signal IN and the inverted input signal ZIN. The drain terminal of the N-type transistor M_{N1} is connected to the node a. The source terminal of the N-type transistor M_{N1} receives the ground voltage GND. The gate terminal of the N-type transistor M_{N1} receives the input signal IN. The drain terminal of the N-type transistor M_{N2} is connected to the node b. The source terminal of the N-type transistor M_{N2} receives the ground voltage GND. The gate terminal of the N-type transistor M_{N2} receives the inverted input signal ZIN.

In case that the input signal IN of the level shifter 110 is the supply voltage V_{DD1} (i.e., the logic high level) and the inverted input signal ZIN is the ground voltage GND (i.e., the logic low level), the N-type transistor M_{N1} and the P-type transistor M_{P2} are turned on, and the N-type transistor M_{N2} and the P-type transistor M_{P1} are turned off. Consequently, the voltage at the node b is the supply voltage V_{DD2}, and the output signal OUT is the supply voltage V_{DD2} (i.e., the logic high level). In other words, the supply voltage V_{DD1} with the logic high level is converted into the supply voltage V_{DD2} with another logic high level by the level shifter 110.

In case that the input signal IN of the level shifter 110 is the ground voltage GND (i.e., the logic low level) and the inverted input signal ZIN is the supply voltage V_{DD1} (i.e., the logic high level), the N-type transistor M_{N1} and the P-type transistor M_{P2} are turned off, and the N-type transistor M_{N2} and the P-type transistor M_{P1} are turned on. Consequently, the voltage at the node b is the ground voltage GND, and the output signal OUT is the ground voltage GND. In other words, the ground voltage GND with the logic low level is converted into the same ground voltage GND with the logic low level by the level shifter 110.

As mentioned above, the maximum voltage stress that can be withstood by each of the four transistors M_{P1}, M_{P2}, M_{N1} and M_{N2} in the level shifter 110 of FIG. 1B is approximately equal to the supply voltage V_{DD2}. That is, the four transistors M_{P1}, M_{P2}, M_{N1} and M_{N2} in the conventional level shifter 110 must be medium voltage devices (MV devices). Generally, the threshold voltage of each of the N-type transistors M_{N1} and M_{N2} produced by using the manufacturing process for the MV devices is very close to the supply voltage V_{DD1}. In other words, when the gate terminal of the N-type transistor M_{N1} or N-type transistor M_{N2} in the differential pair circuit 114 receives the supply voltage V_{DD1}, the N-type transistor M_{N1} or N-type transistor M_{N2} cannot be turned on completely. Since the driving capability of M_{N1} or N-type transistor M_{N2} is insufficient, the operating speed of the level shifter 110 cannot be increased.

### SUMMARY OF THE INVENTION

An embodiment of the present invention provides a level shifter for converting an input signal between a first supply voltage and a ground voltage into an output signal between a second supply voltage and the ground voltage. The second supply voltage is greater than the first supply voltage. The level shifter includes a first P-type transistor, a second P-type transistor, a first N-type transistor, a second N-type transistor, a third N-type transistor, a fourth N-type transistor and a pulling device. A source terminal of the first P-type transistor receives the second supply voltage. A drain terminal of the first P-type transistor is coupled to a first node. A gate terminal of the first P-type transistor is coupled to a second node. A voltage at the node b is used as the output signal. A source terminal of the second P-type transistor receives the second supply voltage. A drain terminal of the second P-type transistor is coupled to the second node. A gate terminal of the second P-type transistor is coupled to the first node. A source terminal of the first N-type transistor receives the ground voltage. A drain terminal of the first N-type transistor is coupled to a third node. A gate terminal of the first N-type transistor receives the input signal. A source terminal of the second N-type transistor receives the ground voltage. A drain terminal of the second N-type transistor is coupled to a fourth node. A gate terminal of the second N-type transistor receives an inverted input signal. The input signal and the inverted input signal are complementary to each other. A source terminal of the third N-type transistor is coupled to the third node. A drain terminal of the third N-type transistor is coupled to the first node. A gate terminal of the third N-type transistor receives the input signal. A source terminal of the fourth N-type transistor is coupled to the fourth node. A drain terminal of the fourth N-type transistor is coupled to the second node. A gate terminal of the fourth N-type transistor receives the inverted input signal. The pulling device is connected to the second node. The pulling device receives an enable signal. When at least one of the first supply voltage and the second supply voltage is not provided and the enable signal is not activated, the pulling device is turned on and the output signal is maintained at a specified logic level. When the first supply voltage and the second supply voltage are both provided and the enable signal is activated, the pulling device is turned off and the output signal changes with a change of the input signal.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1A (prior art) is a schematic circuit diagram illustrating the operations of the circuits between different power domains in an IC chip;

FIG. 1B (prior art) is a schematic circuit diagram of a conventional level shifter;

FIG. 2 is a schematic circuit diagram illustrating the circuitry structure of a level shifter according to a first embodiment of the present invention;

FIG. 3A is a schematic circuit diagram illustrating the circuitry structure of a level shifter according to a second embodiment of the present invention;

FIG. 3B is a schematic circuit diagram illustrating an example of the pulling device in the level shifter of FIG. 3A;

FIG. 3C is a schematic circuit diagram illustrating another example of the pulling device in the level shifter of FIG. 3A;

FIG. 4 is a schematic circuit diagram illustrating the circuitry structure of a level shifter according to a third embodiment of the present invention;

FIGS. 5A and 5B are schematic circuit diagrams illustrating the circuitry structure of the level shifter of the third embodiment, in which a P-type transistor is used as the pulling device;

FIG. 6A is a schematic circuit diagram illustrating the circuitry structure of a level shifter according to a fourth embodiment of the present invention;

FIG. 6B is a schematic circuit diagram illustrating the circuitry structure of a level shifter according to a fifth embodiment of the present invention;

FIG. 6C is a schematic circuit diagram illustrating the circuitry structure of a level shifter according to a sixth embodiment of the present invention;

FIGS. 7A and 7B are schematic circuit diagrams illustrating the circuitry structure of the level shifter of the third embodiment, in which an N-type transistor is used as the pulling device;

FIG. 8A is a schematic circuit diagram illustrating the circuitry structure of a level shifter according to a seventh embodiment of the present invention;

FIG. 8B is a schematic circuit diagram illustrating the circuitry structure of a level shifter according to an eighth embodiment of the present invention;

FIG. 8C is a schematic circuit diagram illustrating the circuitry structure of a level shifter according to a ninth embodiment of the present invention;

FIG. 8D is a schematic circuit diagram illustrating the circuitry structure of a level shifter according to a tenth embodiment of the present invention;

FIG. 8E is a schematic circuit diagram illustrating the circuitry structure of a level shifter according to an eleventh embodiment of the present invention; and

FIG. 8F is a schematic circuit diagram illustrating the circuitry structure of a level shifter according to a twelfth embodiment of the present invention.

### DETAILED DESCRIPTION OF PREFERRED EMBODIMENTS

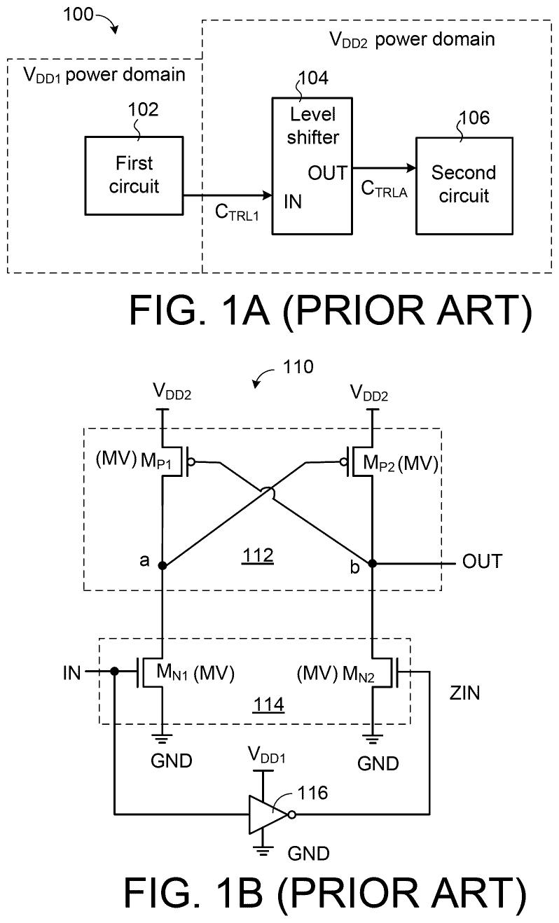

The present invention provides a level shifter. The level shifter of the present invention can be applied to the IC chip 100 shown in FIG. 1A. Furthermore, the level shifter of the present invention includes MV devices and LV devices.

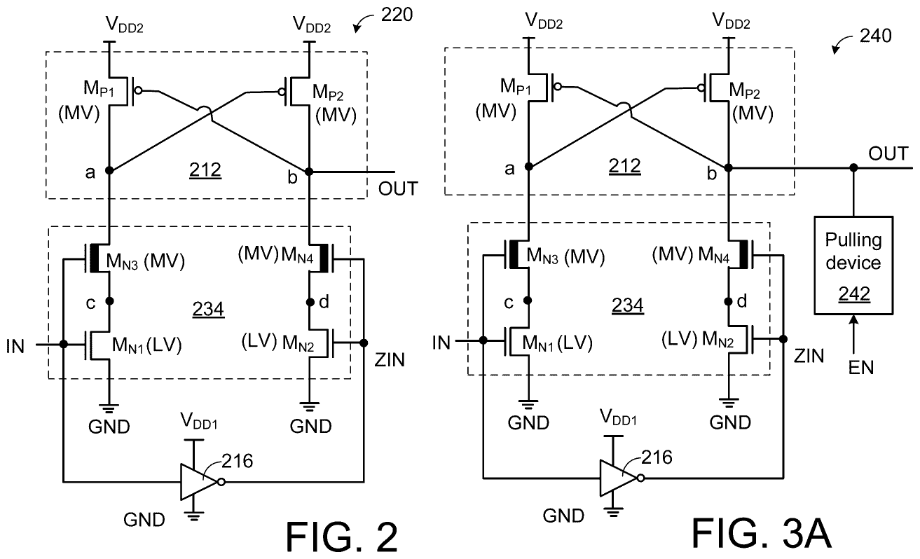

FIG. 2 is a schematic circuit diagram illustrating the circuitry structure of a level shifter according to a first embodiment of the present invention. The level shifter includes MV devices and LV devices. As shown in FIG. 2, the level shifter 220 includes a NOT gate 216, a cross-coupled circuit 212 and a differential pair circuit 234. The NOT gate 216 is included in the V_{DD1} power domain, and the cross-coupled circuit 212 and the differential pair circuit 234 are included in the V_{DD2} power domain.

The two power terminals of the NOT gate 216 are respectively connected to the supply voltage V_{DD1} and the ground voltage GND. The input terminal of the NOT gate 216 receives an input signal IN. The output terminal of the NOT gate 216 generates an inverted input signal ZIN. The input signal IN and the inverted input signal ZIN are complementary to each other.

The cross-coupled circuit 212 includes a P-type transistor M_{P1} and a P-type transistor M_{P2}. The cross-coupled circuit 212 is connected to the node a and the node b. In addition, the cross-coupled circuit 212 receives the supply voltage V_{DD2}. The source terminal of the P-type transistor M_{P1} receives the supply voltage V_{DD2}. The drain terminal of the P-type transistor M_{P1} is coupled to the node a. The gate terminal of the P-type transistor M_{P1} is coupled to the node b. The source terminal of P-type transistor M_{P2} receives the supply voltage V_{DD2}. The drain terminal of P-type transistor MP₂ is coupled to the node b. The gate terminal of P-type transistor MP₂ is coupled to the node a. The voltage at the node b is used as the output signal OUT.

The differential pair circuit 234 is connected to the node a and the node b. In addition, the differential pair circuit 234 receives the ground voltage GND, the input signal IN and the inverted input signal ZIN. The differential pair circuit 234 includes an N-type transistor M_{N1}, an N-type transistor M_{N2}, an N-type transistor M_{N3} and an N-type transistor M_{N4}. The drain terminal of the N-type transistor M_{N3} is coupled to the node a. The source terminal of the N-type transistor M_{N3} is coupled to the node c. The gate terminal of the N-type transistor M_{N3} receives the input signal IN. The drain terminal of the N-type transistor M_{N4} is coupled to the node b. The source terminal of the N-type transistor M_{N4} is coupled to the node d. The gate terminal of the N-type transistor M_{N4} receives the inverted input signal ZIN. The drain terminal of the N-type transistor M_{N1} is coupled to the node c. The source terminal of the N-type transistor M_{N1} receives the ground voltage GND. The gate terminal of the N-type transistor M_{N1} receives the input signal IN. The drain terminal of the N-type transistor M_{N2} is coupled to the node d. The source terminal of the N-type transistor M_{N2} receives the ground voltage GND. The gate terminal of the N-type transistor M_{N2} receives the inverted input signal ZIN.

In this embodiment, the N-type transistor M_{N1} and the N-type transistor M_{N2} are LV devices, and the P-type transistor M_{P1}, the P-type transistor M_{P2}, the N-type transistors M_{N3} and the N-type transistors M_{N4} are MV devices. In addition, the P-type transistor M_{P1}, the P-type transistor M_{P2}, the N-type transistors M_{N1} and the N-type transistors M_{N2} are MOSFET transistors. The N-type transistor M_{N3} and the N-type transistor M_{N4} are native transistors, which are also referred to as depletion-mode transistors. The native transistor is a transistor with initial conductive characteristics (i.e., already-on characteristics). The threshold voltage Vt of the native transistor is very low, e.g., approximately in the range between −0.3V and +0.3V.

In case that the input signal IN of the level shifter 220 is the supply voltage V_{DD1} (i.e., the logic high level) and the inverted input signal ZIN is the ground voltage GND (i.e., the logic low level), the N-type transistor M_{N1}, the N-type transistor M_{N3} and the P-type transistor M_{P2} are turned on, and the N-type transistor M_{N2}, the N-type transistor M_{N4} and P-type transistor M_{P1} are turned off. Consequently, the voltage at the node b is the supply voltage V_{DD2}, and the output signal OUT is the supply voltage V_{DD2} (i.e., the logic high level). In other words, the supply voltage V_{DD1} with the logic high level is converted into the supply voltage V_{DD2} with another logic high level by the level shifter 220.

In case that the input signal IN of the level shifter 220 is the ground voltage GND (i.e., the logic low level) and the inverted input signal ZIN is the supply voltage V_{DD1} (i.e., the logic high level), the N-type transistor M_{N1}, the N-type transistor M_{N3} and the P-type transistor M_{P2} are turned off, and the N-type transistor M_{N2}, the N-type transistor M_{N4} and P-type transistor M_{P1} are turned on. Consequently, the voltage at the node b is the ground voltage GND, and the output signal OUT is the ground voltage GND. In other words, the ground voltage GND with the logic low level is converted into the same ground voltage GND with the logic low level by the level shifter 220.

In the differential pair circuit 234 of the level shifter 220 of FIG. 2, the N-type transistor M_{N4} is the MV device, and the N-type transistor M_{N2} is the LV device. In case that the output signal OUT is the supply voltage V_{DD2} (i.e., the logic high level), the N-type transistor M_{N4} and the N-type transistor M_{N2} both withstand the voltage stress of the supply voltage V_{DD2}. Since a portion of the voltage stress is shared by the N-type transistor M_{N4}, the N-type transistor M_{N2} can be implemented with an LV device. Similarly, the N-type transistor M_{N1} can be implemented with an LV device.

Furthermore, since the N-type transistor M_{N1} and the N-type transistor M_{N2} are LV devices, their threshold voltages Vt are very low. For example, the threshold voltage Vt is about a half of the supply voltage V_{DD1}. When the gate terminal of the N-type transistor M_{N1} or the N-type transistor M_{N2} receives the supply voltage V_{DD1}, the N-type transistor M_{N1} or the N-type transistor M_{N2} can be turned on completely. Consequently, the level shifter 220 can be operated normally, and the operating speed of the level shifter 220 can be increased.

Furthermore, in the IC chip 100 of FIG. 1A, the sequence of providing the supply voltages V_{DD1} and V_{DD2} may influence the operations of the level shifter 220 and cause the malfunction of the second circuit 106. For example, in the IC chip 100, the supply voltage V_{DD2} is first provided. Meanwhile, since the supply voltage V_{DD1} has not been provided, the logic level of the input signal IN cannot be determined. Since the logic level of the output signal OUT cannot be determined, the malfunction of the second circuit 106 occurs.

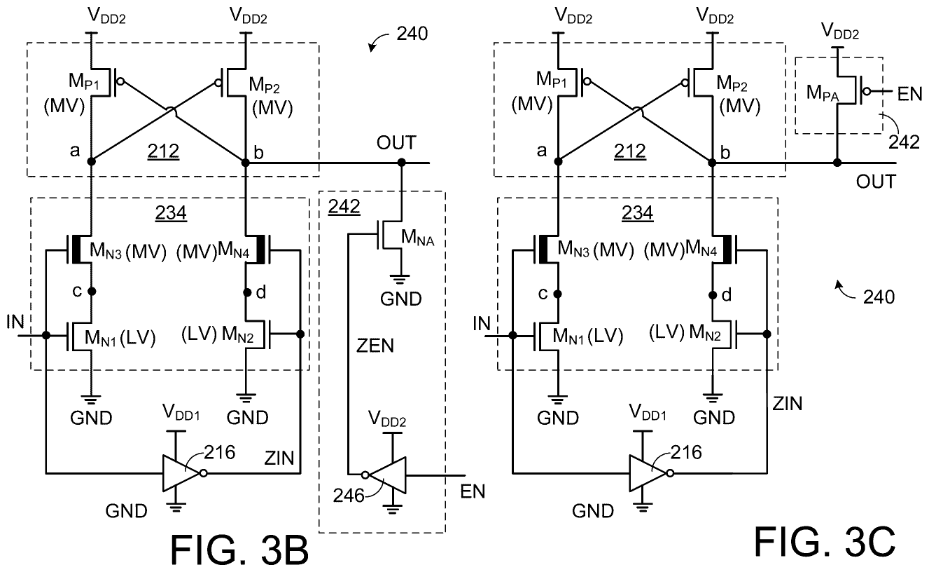

In order to overcome the above drawbacks, the level shifter needs to be modified. FIG. 3A is a schematic circuit diagram illustrating the circuitry structure of a level shifter according to a second embodiment of the present invention. In comparison with the level shifter 220 of the first embodiment, the level shifter 240 of this embodiment further includes a pulling device 242. For brevity, only the connecting relationships between the pulling device 242 and associated components will be described as follows.

The pulling device 242 is connected to the node b. In addition, the pulling device 242 receives an enable signal EN. The pulling device 242 is designed in the power domain V_{DD2}. For example, the enable signal EN is a power enable signal. When the enable signal EN is activated, it means that the supply voltage V_{DD1} and the supply voltage V_{DD2} are both provided and the IC chip 100 and the level shifter 240 can be operated normally. When the enable signal EN is not activated, it means that the at least one of the supply voltage V_{DD1} and the supply voltage V_{DD2} is not provided and IC chip 100 and the level shifter 240 cannot be operated normally. For example, the enable signal EN is activated when the voltage level of the enable signal EN is at the logic high level V_{DD2}, and the enable signal EN is not activated when the voltage level of the enable signal EN is at the logic low level GND.

In case that the enable signal EN is not activated, the pulling device 242 is connected to the node b, and the voltage at the node b is pulled to a specified logic level. Consequently, the output signal OUT is maintained at the specified logic level. In case that the enable signal EN is activated, the pulling device 242 is disconnected from the node b, and the voltage at the node b is no longer pulled to the specified logic level. Consequently, the output signal OUT is subjected to a change with the change of the input signal IN.

Hereinafter, two examples of the pulling device 242 will be described as follows. FIG. 3B is a schematic circuit diagram illustrating an example of the pulling device in the level shifter of FIG. 3A. FIG. 3C is a schematic circuit diagram illustrating another example of the pulling device in the level shifter of FIG. 3A.

In the example of FIG. 3B, the pulling device 24 includes an N-type transistor M_{NA} and a NOT gate 246. The two power terminals of the NOT gate 246 are respectively connected to the supply voltage V_{DD2} and the ground voltage GND. The input terminal of the NOT gate 246 receives the enable signal EN. The output terminal of the NOT gate 246 generates an inverted enable signal ZEN. The enable signal EN and the inverted enable signal ZEN are complementary to each other. The drain terminal of the N-type transistor M_{NA} is connected to the node b. The source terminal of the N-type transistor M_{NA} receives the ground voltage GND. The gate terminal of the N-type transistor M_{NA} receives the inverted enable signal ZEN. Furthermore, the N-type transistor M_{NA} is a MOSFET transistor, and the N-type transistor M_{NA} is a MV device.

In case that the enable signal EN is not activated, the voltage level of the enable signal EN is at the logic low level GND, and the voltage level of the inverted enable signal ZEN is the logic high level V_{DD2}. Meanwhile, the N-type transistor M_{NA} is turned on, and the voltage at the node b is pulled down to the ground voltage GND, indicating that the output signal OUT has the logic low level. In case that the enable signal EN is activated, the voltage level of the enable signal EN is at the logic high level V_{DD2}, and the voltage level of the inverted enable signal ZEN is the logic low level GND. Meanwhile, the N-type transistor M_{NA} is turned off, and the output signal OUT is subjected to a change with the change of the input signal IN.

In the example of FIG. 3C, the pulling device 242 includes a P-type transistor M_{PA}. The drain terminal of the P-type transistor M_{PA} is connected to the node b. The source terminal of the P-type transistor M_{NA} receives the supply voltage V_{DD2}. The gate terminal of the P-type transistor M_{PA} receives the enable signal EN. Furthermore, the P-type transistor M_{PA} is a MOSFET transistor, and the P-type transistor M_{PA} is a MV device.

In case that the enable signal EN is not activated, the voltage level of the enable signal EN is at the logic low level GND. Meanwhile, the P-type transistor M_{PA} is turned on, and the voltage at the node b is pulled up to the supply voltage V_{DD2}, indicating that the output signal OUT has the logic high level. In case that the enable signal EN is activated, the voltage level of the enable signal EN is at the logic high level V_{DD2}. Meanwhile, the P-type transistor M_{PA} is turned off, and the output signal OUT is subjected to a change with the change of the input signal IN.

It is noted that numerous modifications or alterations may be made. For example, the logic level of the enable signal EN corresponding to the activated state or the inactivated may be varied. In a variant example, the enable signal EN is activated when the voltage level of the enable signal EN is at the logic low level GND, and the enable signal EN is not activated when the voltage level of the enable signal EN is at the logic high level V_{DD2}. Under this circumstance, the connecting relationships between the transistor of pulling device 242 and associated components need to be modified.

However, during the operation of the level shifter 240 of the second embodiment in response to the activated state of the enable signal EN, the node c or the node d is possibly in the floating state. For example, in case that the input signal IN is the supply voltage V_{DD1} and the inverted input signal ZIN is the ground voltage GND, the N-type transistor M_{N4} and the N-type transistor M_{N2} are turned off. Under this circumstance, the node d is in the floating state, and the voltage at the node d is unable to be confirmed. Similarly, in case that the input signal IN is the ground voltage GND and the inverted input signal ZIN is the supply voltage V_{DD1}, the N-type transistor M_{N3} and the N-type transistor M_{N1} are turned off. Under this circumstance, the node c is in the floating state, and the voltage at the node c is unable to be confirmed.

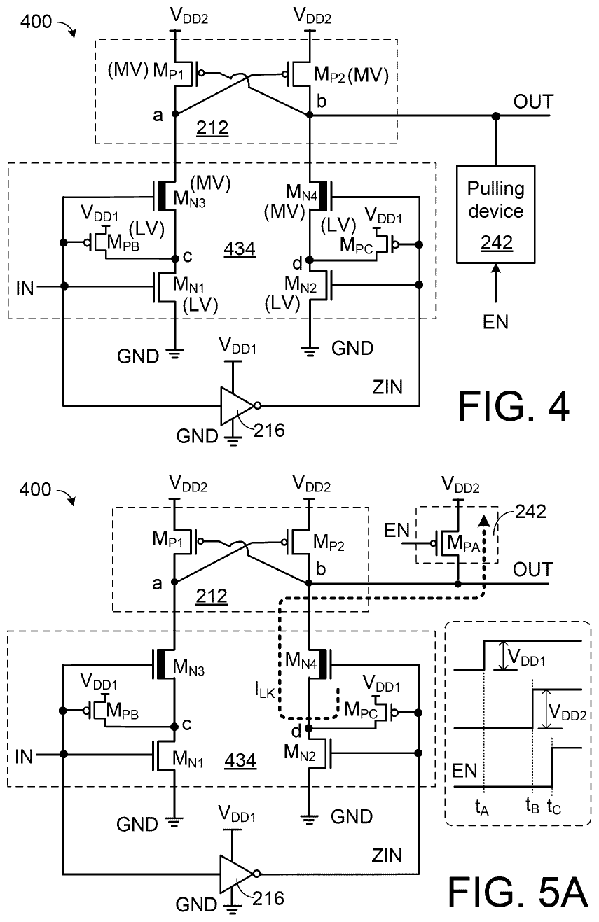

In order to overcome the above drawbacks, the level shifter needs to be modified. FIG. 4 is a schematic circuit diagram illustrating the circuitry structure of a level shifter according to a third embodiment of the present invention. In comparison with the level shifter 240 of the second embodiment, the differential pair circuit 434 in the level shifter 400 of this embodiment is distinguished. For brevity, only the connecting relationships of the differential pair circuit 434 in the level shifter 400 will be described as follows.

The differential pair circuit 434 is connected to the node a and the node b. In addition, the differential pair circuit 434 receives the ground voltage GND, the supply voltage V_{DD1}, the input signal IN and the inverted input signal ZIN. The differential pair circuit 434 includes an N-type transistor M_{N1}, an N-type transistor M_{N2}, an N-type transistor M_{N3}, an N-type transistor M_{N4}, a P-type transistor M_{PB} and a P-type transistor M_{PC}.

The N-type transistors M_{N1}, M_{N2}, M_{N3} and M_{N4} are included in the power domain V_{DD2}. The N-type transistor M_{N1}, the N-type transistor M_{N2}, the P-type transistor M_{PB} and the P-type transistor M_{PC} are LV devices. The N-type transistor M_{N3} and the N-type transistor M_{N4} are MV devices. In addition, the N-type transistor M_{N1}, the N-type transistor M_{N2}, the P-type transistor M_{PB} and the P-type transistor M_{PC} are MOSFET transistors. The N-type transistor M_{N3} and the N-type transistor M_{N4} are native transistors, which are also referred to as depletion-mode transistors.

In the differential pair circuit 434, the drain terminal of the N-type transistor M_{N3} is coupled to the node a, the source terminal of the N-type transistor M_{N3} is coupled to the node c, and the gate terminal of the N-type transistor M_{N3} receives the input signal IN. The drain terminal of the N-type transistor M_{N4} is coupled to the node b. The source terminal of the N-type transistor M_{N4} is coupled to the node d. The gate terminal of the N-type transistor M_{N4} receives the inverted input signal ZIN. The drain terminal of the N-type transistor M_{N1} is coupled to the node c. The source terminal of the N-type transistor M_{N1} receives the ground voltage GND. The gate terminal of the N-type transistor M_{N1} receives the input signal IN. The drain terminal of the N-type transistor M_{N2} is coupled to the node d. The source terminal of the N-type transistor M_{N2} receives the ground voltage GND. The gate terminal of the N-type transistor M_{N2} receives the inverted input signal ZIN. The source terminal of the P-type transistor M_{PB} receives the supply voltage VDD1. The drain terminal of the P-type transistor M_{PB} is coupled to the node c. The gate terminal of the P-type transistor M_{PB} receives the input signal IN. The source terminal of the P-type transistor M_{PC} receives the supply voltage V_{DD1}. The drain terminal of the P-type transistor M_{PC} is coupled to the node d. The gate terminal of the P-type transistor M_{PC} receives the inverted input signal ZIN.

When the enable signal EN is activated, the level shifter 400 can be operated normally. In case that the input signal IN is the supply voltage V_{DD1} and the inverted input signal ZIN is the ground voltage GND, the N-type transistor M_{N1} and the N-type transistor M_{N3} are turned on, and the P-type transistor M_{PB} is turned off. The voltage at each of the node c and the node a is the ground voltage GND. Furthermore, the N-type transistor M_{N2} and the N-type transistor M_{N4} are turned off, and the P-type transistor M_{PC} is turned on. The voltage at the node d is the supply voltage V_{DD1}. The voltage at the node b is the supply voltage V_{DD2}. In other words, the output signal OUT has the logic high level V_{DD2}.

In case that the input signal IN is the ground voltage GND and the inverted input signal ZIN is the supply voltage V_{DD1}, the N-type transistor M_{N1} and the N-type transistor M_{N3} are turned off, and the P-type transistor M_{PB} is turned on. The voltage at the node c is the supply voltage V_{DD1}. The voltage at the node a is the supply voltage V_{DD2}. Furthermore, the N-type transistor M_{N2} and the N-type transistor M_{N4} are turned on, and the P-type transistor M_{PC} is turned off. The voltage at each of the node d and the node b is the ground voltage GND. In other words, the output signal OUT has the logic low level GND.

As mentioned above, when the enable signal EN is activated and the level shifter 400 is operated normally, the node c and the node d will not be in the floating state. However, although the level shifter 400 can be operated normally, the sequence of providing the supply voltages V_{DD1} and V_{DD2} may cause the level shifter 400 to generate a leakage current.

Hereinafter, the level shifter with the pulling device 242 of FIG. 3C and the level shifter with the pulling device 242 of FIG. 3B will be illustrated to explain the reasons why the leakage current is generated. Furthermore, some improved embodiments of the level shifter to eliminate the leakage current will be provided.

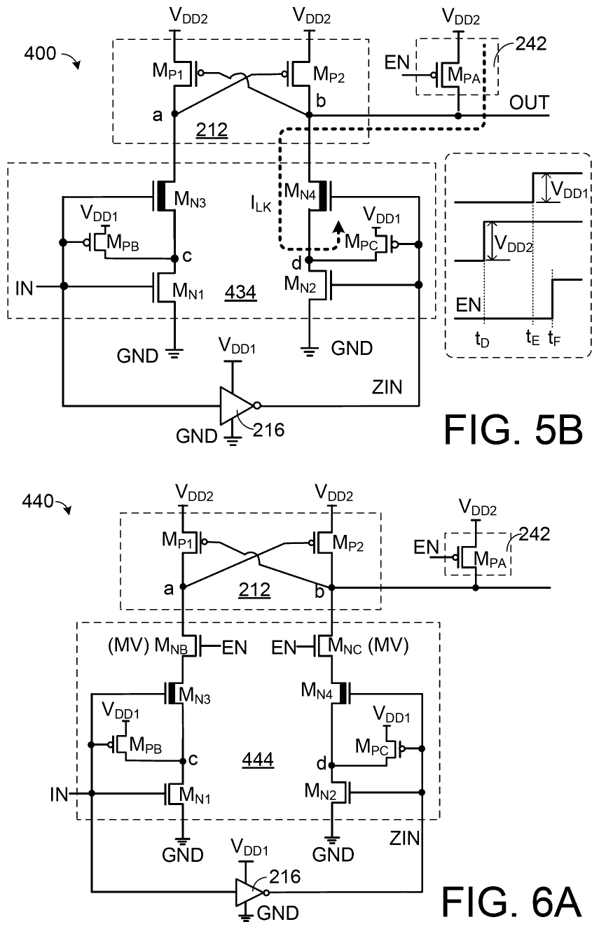

FIGS. 5A and 5B are schematic circuit diagrams illustrating the circuitry structure of the level shifter of the third embodiment, in which a P-type transistor is used as the pulling device. Like the example of FIG. 3C, the pulling device 242 includes the P-type transistor M_{PA}. The source terminal of the P-type transistor M_{NA} receives the supply voltage V_{DD2}. The drain terminal of the P-type transistor M_{PA} is connected to the node b. The gate terminal of the P-type transistor M_{PA} receives the enable signal EN.

Please refer to FIG. 5A. At the time point t_{A}, the level shifter 400 receives the supply voltage V_{DD1}. At the time point t_{B}, the level shifter 400 receives the supply voltage V_{DD2}. At the time point t_{C}, the enable signal EN is activated.

When the time point t_{A} at which the supply voltage V_{DD1} is provided is earlier than the time point t_{B} at which the supply voltage V_{DD2} is provided, the level shifter 400 generates at least one leakage current path. For example, in the time interval between the time point t_{A} and the time point t_{B}, a leakage current I_{LK} flows from the voltage source of the supply voltage V_{DD1} to the voltage source of the supply voltage V_{DD2} through the P-type transistor M_{PC}, the node d, the N-type transistor M_{N4}, the node b and the P-type transistor M_{PA}.

Please refer to FIG. 5B. At the time point t_{D}, the level shifter 400 receives the supply voltage V_{DD2}. At the time point t_{E}, the level shifter 400 receives the supply voltage V_{DD1}. At the time point t_{F}, the enable signal EN is activated.

When the time point t_{D} at which the supply voltage V_{DD2} is provided is earlier than the time point t_{E} at which the supply voltage V_{DD1} is provided, the level shifter 400 generates at least one leakage current path. For example, in the time interval between the time point t_{D} and the time point t_{E}, a leakage current I_{LK} flows from the voltage source of the supply voltage V_{DD2} to the voltage source of the supply voltage V_{DD1} through the P-type transistor M_{PA}, the node b, the N-type transistor M_{N4}, the node d and the P-type transistor M_{PC}.

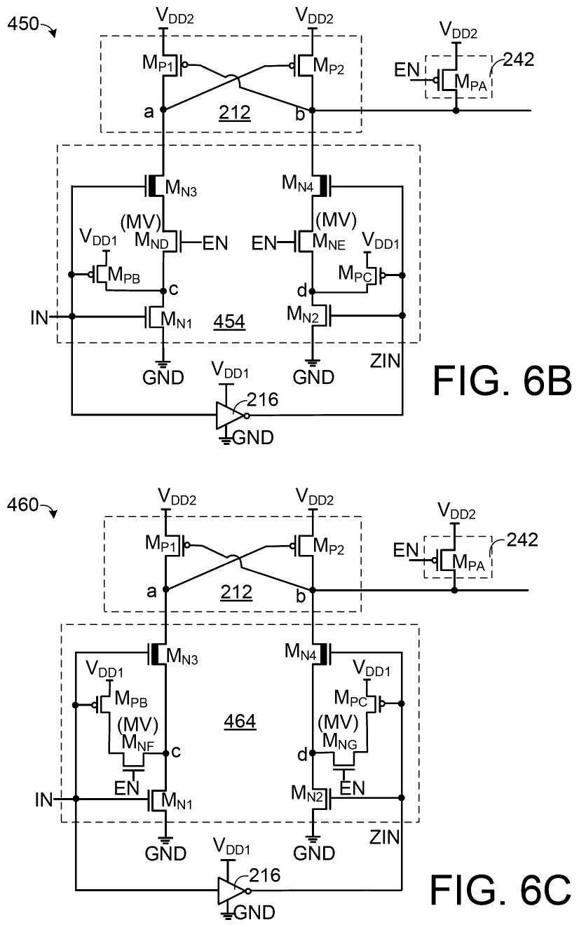

In order to eliminate the leakage current path of FIGS. 5A and 5B, the differential pair circuit 434 in the level shifter 400 of the third embodiment is modified. Hereinafter, three improved embodiments of the level shifter will be described with reference to FIGS. 6A, 6B and 6C.

FIG. 6A is a schematic circuit diagram illustrating the circuitry structure of a level shifter according to a fourth embodiment of the present invention. In comparison with the differential pair circuit 434 in the level shifter 400 of the third embodiment, the differential pair circuit 444 in the level shifter 440 of the fourth embodiment further includes an N-type transistor M_{NB} and an N-type transistor M_{NC}. The N-type transistor M_{NB} and the N-type transistor M_{NC} are MOSFET transistors. In addition, the N-type transistor M_{NB} and the N-type transistor M_{NC} are MV devices. For brevity, only the connecting relationships between the N-type transistor M_{NB}, the N-type transistor M_{NC} and associated components will be described as follows.

In the differential pair circuit 444, the drain terminal of the N-type transistor M_{N3} is coupled to the node a through the N-type transistor M_{NB}, and the drain terminal of the N-type transistor M_{N4} is coupled to the node b through the N-type transistor M_{NC}. The drain terminal of the N-type transistor M_{NB} is connected to the node a. The source terminal of the N-type transistor M_{NB} is connected to the drain terminal of the N-type transistor M_{N3}. The gate terminal of the N-type transistor M_{NB} receives the enable signal EN. The drain terminal of the N-type transistor M_{NC} is connected to the node b. The source terminal of the N-type transistor M_{NC} is connected to the drain terminal of the N-type transistor M_{N4}. The gate terminal of the N-type transistor M_{NC} receives the enable signal EN.

Even if the supply voltages V_{DD1} and V_{DD2} are not simultaneously provided before the enable signal EN is activated, the leakage current path will not be generated because the N-type transistor M_{NB} and the N-type transistor M_{NC} are turned off. In other words, the differential pair circuit 444 in the level shifter 440 can effectively avoid the generation of the leakage current.

FIG. 6B is a schematic circuit diagram illustrating the circuitry structure of a level shifter according to a fifth embodiment of the present invention. In comparison with the differential pair circuit 434 in the level shifter 400 of the third embodiment, the differential pair circuit 454 in the level shifter 450 of the fifth embodiment further includes an N-type transistor M_{ND} and an N-type transistor M_{NE}. The N-type transistor M_{ND} and the N-type transistor M_{NE} are MOSFET transistors. In addition, the N-type transistor M_{ND} and the N-type transistor M_{NE} are MV devices. For brevity, only the connecting relationships between the N-type transistor M_{ND}, the N-type transistor M_{NE} and associated components will be described as follows.

In the differential pair circuit 454, the source terminal of the N-type transistor M_{N3} is coupled to the node c through the N-type transistor M_{ND}, and the source terminal of the N-type transistor M_{N4} is coupled to the node d through the N-type transistor M_{NE}. The drain terminal of the N-type transistor M_{ND} is connected to the source terminal of the N-type transistor M_{N3}. The source terminal of the N-type transistor M_{ND} is connected to the node c. The gate terminal of the N-type transistor M_{ND} receives the enable signal EN. The drain terminal of the N-type transistor M_{NE} is connected to the source terminal of the N-type transistor M_{N4}. The source terminal of the N-type transistor M_{NE} is connected to the node d. The gate terminal of the N-type transistor M_{NE} receives the enable signal EN.

Even if the supply voltages V_{DD1} and V_{DD2} are not simultaneously provided before the enable signal EN is activated, the leakage current path will not be generated because the N-type transistor M_{ND} and the N-type transistor M_{NE} are turned off. In other words, the differential pair circuit 454 in the level shifter 450 can effectively avoid the generation of the leakage current.

FIG. 6C is a schematic circuit diagram illustrating the circuitry structure of a level shifter according to a sixth embodiment of the present invention. In comparison with the differential pair circuit 434 in the level shifter 400 of the third embodiment, the differential pair circuit 464 in the level shifter 460 of the fifth embodiment further includes an N-type transistor M_{NF} and an N-type transistor M_{NG}. The N-type transistor M_{NF} and the N-type transistor M_{NG} are MOSFET transistors. In addition, the N-type transistor M_{NF} and the N-type transistor M_{NG} are MV devices. For brevity, only the connecting relationships between the N-type transistor M_{NF}, the N-type transistor M_{NG} and associated components will be described as follows.

In the differential pair circuit 464, the drain terminal of the P-type transistor M_{PB} is coupled to the node c through the N-type transistor M_{NF}, and the drain terminal of the P-type transistor M_{PC} is coupled to the node d through the N-type transistor M_{NG}. The drain terminal of the N-type transistor M_{NF} is connected to the drain terminal of the P-type transistor M_{PB}. The source terminal of the N-type transistor M_{NF} is connected to the node c. The gate terminal of the N-type transistor M_{NF} receives the enable signal EN. The drain terminal of the N-type transistor M_{NG} is connected to the drain terminal of the P-type transistor M_{PC}. The source terminal of the N-type transistor M_{NG} is connected to the node d. The gate terminal of the N-type transistor M_{NG} receives the enable signal EN.

Even if the supply voltages V_{DD1} and V_{DD2} are not simultaneously provided before the enable signal EN is activated, the leakage current path will not be generated because the N-type transistor M_{NF} and the N-type transistor M_{NG} are turned off. In other words, the differential pair circuit 464 in the level shifter 460 can effectively avoid the generation of the leakage current.

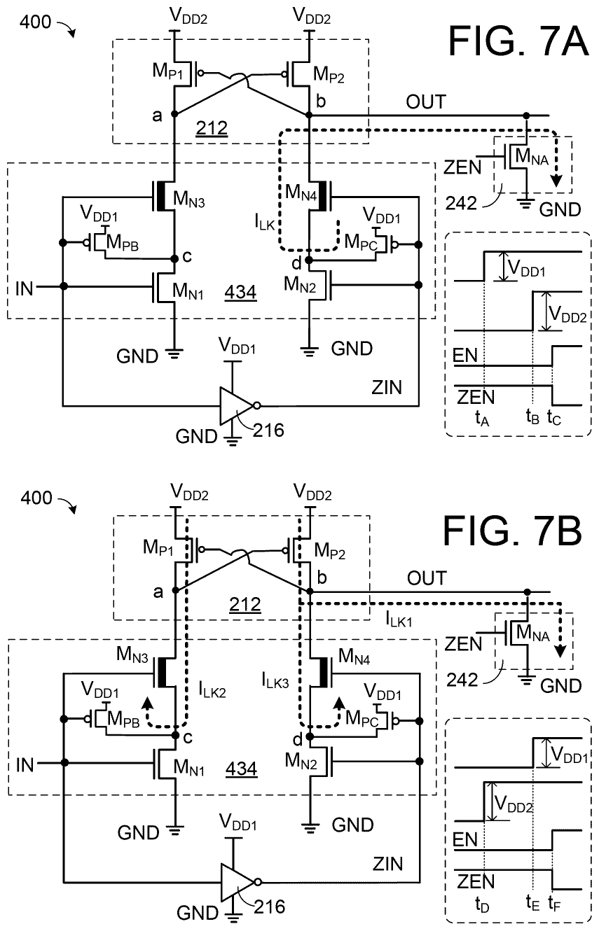

FIGS. 7A and 7B are schematic circuit diagrams illustrating the circuitry structure of the level shifter of the third embodiment, in which an N-type transistor is used as the pulling device. Like the example of FIG. 3B, the pulling device 242 includes the N-type transistor M_{NA}. The source terminal of the N-type transistor M_{NA} receives the ground voltage GND. The drain terminal of the N-type transistor M_{NA} is connected to the node b. The gate terminal of the N-type transistor M_{NA} receives an inverted enable signal ZEN. The enable signal EN and the inverted enable signal ZEN are complementary to each other.

Please refer to FIG. 7A. At the time point t_{A}, the level shifter 400 receives the supply voltage V_{DD1}. At the time point t_{B}, the level shifter 400 receives the supply voltage V_{DD2}. At the time point t_{C}, the enable signal EN is activated.

When the time point t_{A} at which the supply voltage V_{DD1} is provided is earlier than the time point t_{B} at which the supply voltage V_{DD2} is provided, the level shifter 400 generates at least one leakage current path. For example, in the time interval between the time point t_{A} and the time point t_{B}, a leakage current I_{LK} flows from the voltage source of the supply voltage V_{DD1} to the voltage source of the supply voltage V_{DD2} through the P-type transistor M_{PC}, the node d, the N-type transistor M_{N4}, the node b and the N-type transistor M_{NA}.

Please refer to FIG. 7B. At the time point t_{D}, the level shifter 400 receives the supply voltage V_{DD2}. At the time point t_{E}, the level shifter 400 receives the supply voltage V_{DD1}. At the time point t_{F}, the enable signal EN is activated.

When the time point t_{D} at which the supply voltage V_{DD2} is provided is earlier than the time point t_{E} at which the supply voltage V_{DD1} is provided, the level shifter 400 generates at least one leakage current path. For example, in the time interval between the time point t_{D} and the time point t_{E}, a leakage current I_{LK1} flows from the voltage source of the supply voltage V_{DD2} to the voltage source of the ground voltage GND through the P-type transistor M_{P2}, the node b and the N-type transistor M_{NA}, a leakage current I_{LK2} flows from the voltage source of the supply voltage V_{DD2} to the voltage source of the supply voltage V_{DD1} through the P-type transistor M_{P2}, the node b, the N-type transistor M_{N4}, the node d and the P-type transistor M_{PC}, and a leakage current I_{LK3} flows from the voltage source of the supply voltage V_{DD2} to the voltage source of the supply voltage V_{DD1} through the P-type transistor M_{P1}, the node a, the N-type transistor M_{N3}, the node c and the P-type transistor M_{PB}.

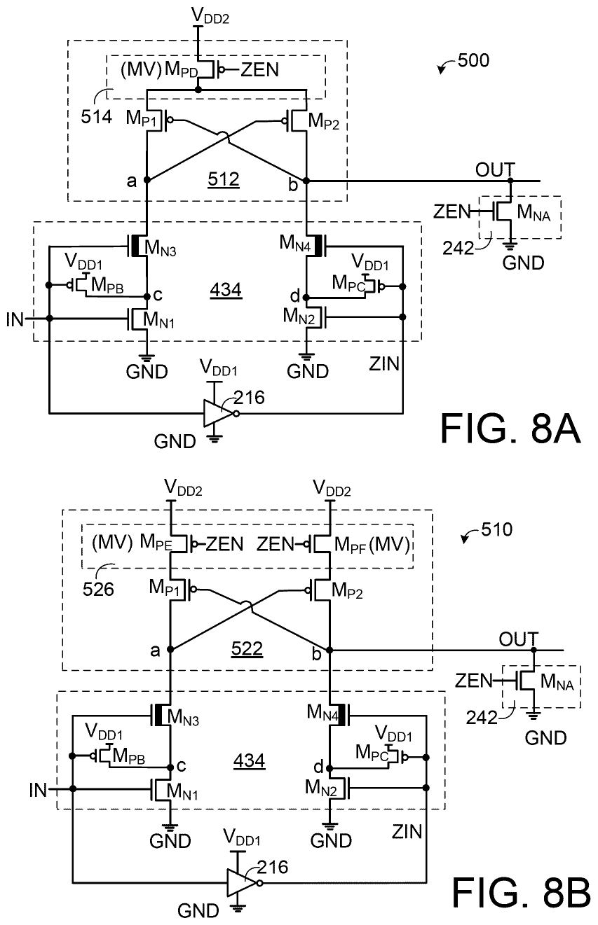

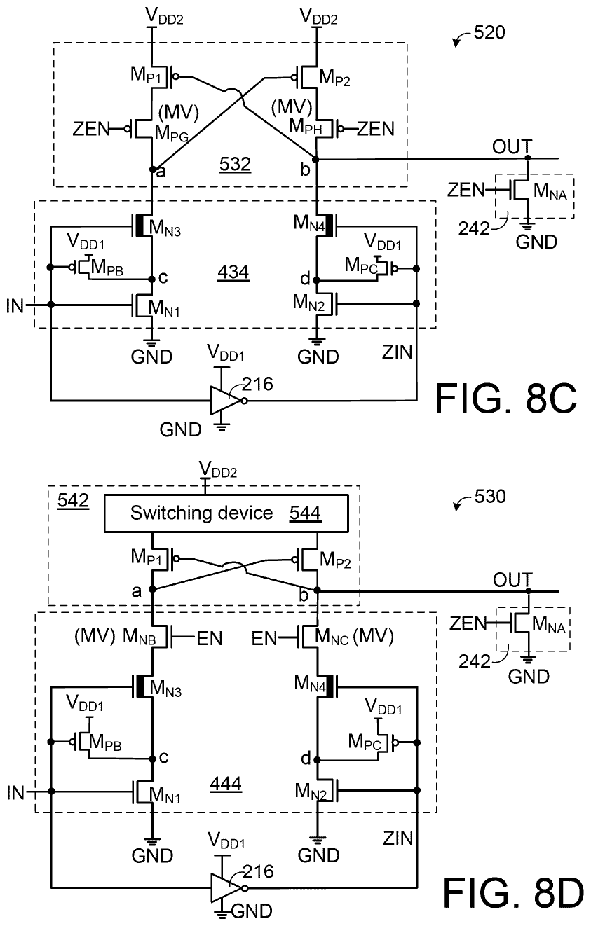

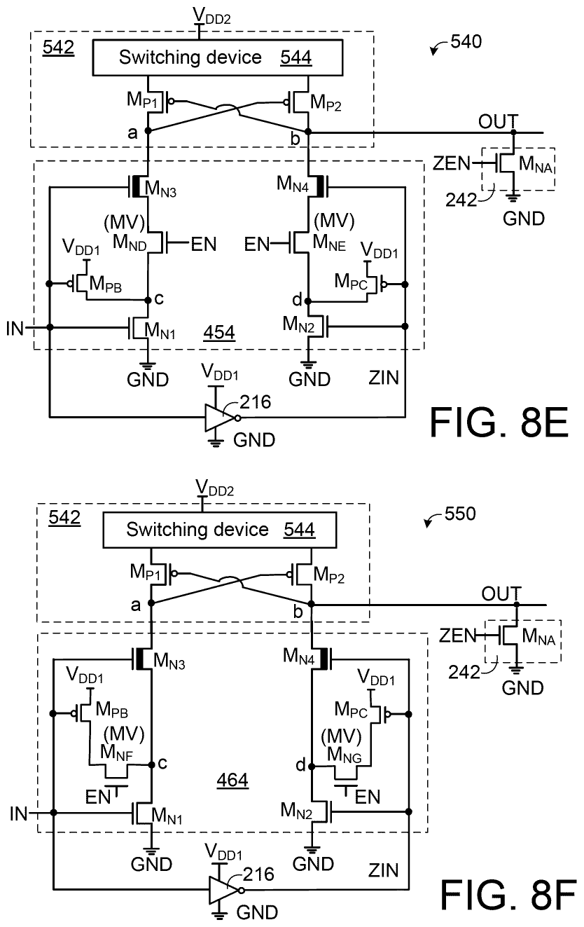

In order to eliminate the leakage current path of FIGS. 7A and 7B, the cross-coupled circuit 212 or the differential pair circuit 434 in the level shifter 400 of the third embodiment are modified. Hereinafter, six improved embodiments of the level shifter will be described with reference to FIGS. 8A, 8B, 8C, 8D, 8E and 8F.

FIG. 8A is a schematic circuit diagram illustrating the circuitry structure of a level shifter according to a seventh embodiment of the present invention. In comparison with the cross-coupled circuit 212 in the level shifter 400 of the third embodiment, the cross-coupled circuit 512 in the level shifter 500 of the seventh embodiment further includes a switching device 514. The switching device 514 includes a P-type transistor M_{PD}. The P-type transistor M_{PD} is a MOSFET transistor. In addition, the P-type transistor M_{PD} is an MV device. For brevity, only the connecting relationships between the switching device 514 and associated components will be described as follows.

In the cross-coupled circuit 512, the source terminal of the P-type transistor M_{P1} receives the supply voltage V_{DD2} through the switching device 514, and the source terminal of the P-type transistor M_{P2} receives the supply voltage V_{DD2} through the switching device 514. The source terminal of the P-type transistor M_{PD} receives the supply voltage V_{DD2}. The drain terminal of the P-type transistor M_{PD} is connected to the source terminal of the P-type transistor M_{P1}. The drain terminal of the P-type transistor M_{PD} is also connected to the source terminal of the P-type transistor M_{P2}. The gate terminal of the P-type transistor M_{PD} receives the inverted enable signal ZEN. The enable signal EN and the inverted enable signal ZEN are complementary to each other.

Even if the supply voltages V_{DD1} and V_{DD2} are not simultaneously provided before the enable signal EN is activated, the leakage current path will not be generated because the P-type transistor M_{PD} is turned off. In other words, the cross-coupled circuit 512 in the level shifter 500 can effectively avoid the generation of the leakage current.

In the seventh embodiment, the switching device 514 of the level shifter 500 includes a single P-type transistor M_{PD}. In some other embodiment, the switching device may include a plurality of P-type transistors.

FIG. 8B is a schematic circuit diagram illustrating the circuitry structure of a level shifter according to an eighth embodiment of the present invention. The cross-coupled circuit 512 in the level shifter 510 of the eighth embodiment further includes a switching device 526. The switching device 526 includes a P-type transistor M_{PE} and a P-type transistor M_{PF}. The P-type transistor M_{PE} and the P-type transistor M_{PF} are MOSFET transistors. In addition, the P-type transistor M_{PE} and the P-type transistor M_{PF} are MV devices. For brevity, only the connecting relationships between the switching device 526 and associated components will be described as follows.

In the cross-coupled circuit 522, the source terminal of the P-type transistor M_{P1} receives the supply voltage V_{DD2} through the switching device 526, and the source terminal of the P-type transistor M_{P2} receives the supply voltage V_{DD2} through the switching device 526. The source terminal of the P-type transistor M_{PE} receives the supply voltage V_{DD2}. The drain terminal of the P-type transistor M_{PE} is connected to the source terminal of the P-type transistor M_{P1}. The gate terminal of the P-type transistor M_{PE} receives the inverted enable signal ZEN. The source terminal of the P-type transistor M_{PF} receives the supply voltage V_{DD2}. The drain terminal of the P-type transistor M_{PF} is connected to the source terminal of the P-type transistor M_{P2}. The gate terminal of the P-type transistor M_{PF} receives the inverted enable signal ZEN.

FIG. 8C is a schematic circuit diagram illustrating the circuitry structure of a level shifter according to a ninth embodiment of the present invention. In comparison with the cross-coupled circuit 212 in the level shifter 400 of the third embodiment, the cross-coupled circuit 532 in the level shifter 520 of the ninth embodiment further includes a P-type transistor M_{PG} and a P-type transistor M_{PH}. The P-type transistor M_{PG} and the P-type transistor M_{PH} are MOSFET transistors. In addition, the P-type transistor M_{PG} and the P-type transistor M_{PH} are MV devices. For brevity, only the connecting relationships between the P-type transistors M_{PG}, M_{PH} and associated components will be described as follows.

In the cross-coupled circuit 532, the drain terminal of the P-type transistor M_{P1} is coupled to the node a through the P-type transistor M_{PG}, and the drain terminal of the P-type transistor M_{P2} is coupled to the node b through the P-type transistor M_{PH}. The source terminal of the P-type transistor M_{PG} is connected to the drain terminal of the P-type transistor M_{P1}. The drain terminal of the P-type transistor M_{PG} is connected to the node a. The gate terminal of the P-type transistor M_{PG} receives the inverted enable signal ZEN. The source terminal of the P-type transistor M_{PH} is connected to the drain terminal of the P-type transistor M_{P2}. The drain terminal of the P-type transistor M_{PH} is connected to the node b. The gate terminal of the P-type transistor M_{PH} receives the inverted enable signal ZEN.

Even if the supply voltages V_{DD1} and V_{DD2} are not simultaneously provided before the enable signal EN is activated, the leakage current path will not be generated because the P-type transistor M_{PG} and the P-type transistor M_{PH} are turned off. In other words, the cross-coupled circuit 532 in the level shifter 530 can effectively avoid the generation of the leakage current.

In some embodiments, one of the cross-coupled circuits 512, 522 and 532 shown in FIGS. 8A, 8B and 8C and one of the differential pair circuits 444, 454 and 464 shown in FIGS. 6A, 6B and 6C are collaboratively included in another level shifter to avoid the generation of the leakage current.

FIG. 8D is a schematic circuit diagram illustrating the circuitry structure of a level shifter according to a tenth embodiment of the present invention. In this embodiment, the level shifter 530 includes a cross-coupled circuit 542 and a differential pair circuit 444. The cross-coupled circuit 542 includes a switching device 544, a P-type transistor M_{P1} and a P-type transistor M_{P2}. The connecting relationships between the switching device 544 and associated components in the cross-coupled circuit 542 are similar to the connecting relationships between the switching device 514 and associated components in the embodiment of FIG. 8A or the connecting relationships between the switching device 526 and associated components in the embodiment of FIG. 8B. The connecting relationships between the differential pair circuit 444 and associated components in this embodiment are similar to the connecting relationships between the differential pair circuit 444 and associated components in the embodiment of FIG. 6A.

FIG. 8E is a schematic circuit diagram illustrating the circuitry structure of a level shifter according to an eleventh embodiment of the present invention. In this embodiment, the level shifter 540 includes a cross-coupled circuit 542 and a differential pair circuit 454. The connecting relationships between the cross-coupled circuit 542 and associated components in this embodiment are similar to the connecting relationships between the cross-coupled circuit 542 and associated components in the embodiment of FIG. 8D. The connecting relationships between the differential pair circuit 454 and associated components in this embodiment are similar to the connecting relationships between the differential pair circuit 454 and associated components in the embodiment of FIG. 6B.

FIG. 8F is a schematic circuit diagram illustrating the circuitry structure of a level shifter according to a twelfth embodiment of the present invention. In this embodiment, the level shifter 550 includes a cross-coupled circuit 542 and a differential pair circuit 464. The connecting relationships between the cross-coupled circuit 542 and associated components in this embodiment are similar to the connecting relationships between the cross-coupled circuit 542 and associated components in the embodiment of FIG. 8D. The connecting relationships between the differential pair circuit 464 and associated components in this embodiment are similar to the connecting relationships between the differential pair circuit 464 and associated components in the embodiment of FIG. 6D.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A level shifter for converting an input signal between a first supply voltage and a ground voltage into an output signal between a second supply voltage and the ground voltage, and the second supply voltage is greater than the first supply voltage, and the level shifter comprising:
a first P-type transistor, wherein a source terminal of the first P-type transistor receives the second supply voltage, a drain terminal of the first P-type transistor is coupled to a first node, and a gate terminal of the first P-type transistor is coupled to a second node, wherein a voltage at the second node is used as the output signal;
a second P-type transistor, wherein a source terminal of the second P-type transistor receives the second supply voltage, a drain terminal of the second P-type transistor is coupled to the second node, and a gate terminal of the second P-type transistor is coupled to the first node;
a first N-type transistor, wherein a source terminal of the first N-type transistor receives the ground voltage, a drain terminal of the first N-type transistor is coupled to a third node, and a gate terminal of the first N-type transistor receives the input signal;
a second N-type transistor, wherein a source terminal of the second N-type transistor receives the ground voltage, a drain terminal of the second N-type transistor is coupled to a fourth node, and a gate terminal of the second N-type transistor receives an inverted input signal, wherein the input signal and the inverted input signal are complementary to each other;
a third N-type transistor, wherein a source terminal of the third N-type transistor is coupled to the third node, a drain terminal of the third N-type transistor is coupled to the first node, and a gate terminal of the third N-type transistor receives the input signal;
a fourth N-type transistor, wherein a source terminal of the fourth N-type transistor is coupled to the fourth node, a drain terminal of the fourth N-type transistor is coupled to the second node, and a gate terminal of the fourth N-type transistor receives the inverted input signal; and
a pulling device connected to the second node, wherein the pulling device receives an enable signal,
wherein when at least one of the first supply voltage and the second supply voltage is not provided and the enable signal is not activated, the pulling device is turned on and the output signal is maintained at a specified logic level, wherein when the first supply voltage and the second supply voltage are both provided, the enable signal is activated, the pulling device is turned off and the output signal changes with a change of the input signal.

2. The level shifter as claimed in claim 1, further comprising:
a third P-type transistor, wherein a source terminal of the third P-type transistor receives the first supply voltage, a drain terminal of the third P-type transistor is coupled to the third node, and a gate terminal of the third P-type transistor receives the input signal; and
a fourth P-type transistor, wherein a source terminal of the fourth P-type transistor receives the first supply voltage, a drain terminal of the fourth P-type transistor is coupled to the fourth node, and a gate terminal of the fourth P-type transistor receives the inverted input signal.

3. The level shifter as claimed in claim 2, wherein the first P-type transistor, the second P-type transistor, the third N-type transistor and the fourth N-type transistor are medium voltage devices, and the third P-type transistor, the fourth P-type transistor, the first N-type transistor and the second N-type transistor are low voltage devices.

4. The level shifter as claimed in claim 3, wherein the first P-type transistor, the second P-type transistor, the third P-type transistor, the fourth P-type transistor, the first N-type transistor and the second N-type transistor are metal oxide semiconductor field effect transistors, and the third N-type transistor and the fourth N-type transistor are depletion-mode transistors.

5. The level shifter as claimed in claim 2, wherein when the enable signal is not activated, a voltage level of the enable signal is at the ground voltage, and when the enable signal is activated, the voltage level of the enable signal is at the second supply voltage.

6. The level shifter as claimed in claim 5, wherein the pulling device comprises a fifth P-type transistor, wherein a source terminal of the fifth P-type transistor receives the second supply voltage, a drain terminal of the fifth P-type transistor is connected to the second node, and a gate terminal of the fifth P-type transistor receives the enable signal.

7. The level shifter as claimed in claim 6, further comprising:
a fifth N-type transistor, wherein the source terminal of the third N-type transistor is coupled to the third node through the fifth N-type transistor; and
a sixth N-type transistor, wherein the source terminal of the fourth N-type transistor is coupled to the fourth node through the sixth N-type transistor,
wherein a drain terminal of the fifth N-type transistor is connected to the source terminal of the third N-type transistor, a source terminal of the fifth N-type transistor is connected to the third node, and a gate terminal of the fifth N-type transistor receives the enable signal, and the fifth N-type transistor is turned on when the enable signal is activated,
wherein a drain terminal of the sixth N-type transistor is connected to the source terminal of the fourth N-type transistor, a source terminal of the sixth N-type transistor is connected to the fourth node, and a gate terminal of the sixth N-type transistor receives the enable signal and the sixth N-type transistor is turned on when the enable signal is activated.

8. The level shifter as claimed in claim 6, further comprising:
a fifth N-type transistor, wherein the drain terminal of the third N-type transistor is coupled to the first node through the fifth N-type transistor; and
a sixth N-type transistor, wherein the drain terminal of the fourth N-type transistor is coupled to the second node through the sixth N-type transistor,
wherein a drain terminal of the fifth N-type transistor is connected to the first node, a source terminal of the fifth N-type transistor is connected to the drain terminal of third N-type transistor, and a gate terminal of the fifth N-type transistor receives the enable signal, and the fifth N-type transistor is turned on when the enable signal is activated,
wherein a drain terminal of the sixth N-type transistor is connected to the second node, a source terminal of the sixth N-type transistor is connected to the drain terminal of the fourth N-type transistor, and a gate terminal of the sixth N-type transistor receives the enable signal, and the sixth N-type transistor is turned on when the enable signal is activated.

9. The level shifter as claimed in claim 6, further comprising:
a fifth N-type transistor, wherein the drain terminal of the third P-type transistor is coupled to the third node through the fifth N-type transistor; and
a sixth N-type transistor, wherein the drain terminal of the fourth P-type transistor is coupled to the fourth node through the sixth N-type transistor,
wherein a drain terminal of the fifth N-type transistor is connected to the drain terminal of the third P-type transistor, a source terminal of the fifth N-type transistor is connected to the third node, and a gate terminal of the fifth N-type transistor receives the enable signal, and the fifth N-type transistor is turned on when the enable signal is activated,
wherein a drain terminal of the sixth N-type transistor is connected to the drain terminal of the fourth P-type transistor, a source terminal of the sixth N-type transistor is connected to the fourth node, and a gate terminal of the sixth N-type transistor receives the enable signal, and the sixth N-type transistor is turned on when the enable signal is activated.

10. The level shifter as claimed in claim 5, wherein the pulling device comprises a fifth N-type transistor, wherein a source terminal of the fifth N-type transistor receives the ground voltage, a drain terminal of the fifth N-type transistor is connected to the second node, and a gate terminal of the fifth N-type transistor receives an inverted enable signal, wherein the enable signal and the inverted enable signal are complementary to each other.

11. The level shifter as claimed in claim 10, further comprising a switching device, wherein the source terminal of the first P-type transistor receives the second supply voltage through the switching device, and the source terminal of the second P-type transistor receives the second supply voltage through the switching device, and the switching device is turned on when the enable signal is activated.

12. The level shifter as claimed in claim 11, wherein the switching device comprises a fifth P-type transistor, wherein a source terminal of the fifth P-type transistor receives the second supply voltage, a drain terminal of the fifth P-type transistor is connected to the source terminal of the first P-type transistor, a drain terminal of the fifth P-type transistor is connected to the source terminal of the second P-type transistor, and a gate terminal of the fifth P-type transistor receives the inverted enable signal, and the fifth P-type transistor is turned on when the enable signal is activated.

13. The level shifter as claimed in claim 11, wherein the switching device comprises a fifth P-type transistor and a sixth P-type transistor, wherein a source terminal of the fifth P-type transistor receives the second supply voltage, a drain terminal of the fifth P-type transistor is connected to the source terminal of the first P-type transistor, and a gate terminal of the fifth P-type transistor receives the inverted enable signal, and the fifth P-type transistor is turned on when the enable signal is activated, wherein a source terminal of the sixth P-type transistor receives the second supply voltage, a drain terminal of the sixth P-type transistor is connected to the source terminal of the second P-type transistor, and a gate terminal of the sixth P-type transistor receives the inverted enable signal, and the sixth P-type transistor is turned on when the enable signal is activated.

14. The level shifter as claimed in claim 11, further comprising:
a sixth N-type transistor, wherein the source terminal of the third N-type transistor is coupled to the third node through the sixth N-type transistor; and
a seventh N-type transistor, wherein the source terminal of the fourth N-type transistor is coupled to the fourth node through the seventh N-type transistor,
wherein a drain terminal of the sixth N-type transistor is connected to the source terminal of the third N-type transistor, a source terminal of the sixth N-type transistor is connected to the third node, and a gate terminal of the sixth N-type transistor receives the enable signal, and the sixth N-type transistor is turned on when the enable signal is activated,
wherein a drain terminal of the seventh N-type transistor is connected to the source terminal of the fourth N-type transistor, a source terminal of the seventh N-type transistor is connected to the fourth node, and a gate terminal of the seventh N-type transistor receives the enable signal, and the seventh N-type transistor is turned on when the enable signal is activated.

15. The level shifter as claimed in claim 11, further comprising:
a sixth N-type transistor, wherein the drain terminal of the third N-type transistor is coupled to the first node through the sixth N-type transistor; and
a seventh N-type transistor, wherein the drain terminal of the fourth N-type transistor is coupled to the second node through the seventh N-type transistor,
wherein a drain terminal of the sixth N-type transistor is connected to the first node, a source terminal of the sixth N-type transistor is connected to the drain terminal of third N-type transistor, and a gate terminal of the sixth N-type transistor receives the enable signal, and the sixth N-type transistor is turned on when the enable signal is activated,
wherein a drain terminal of the seventh N-type transistor is connected to the second node, a source terminal of the seventh N-type transistor is connected to the drain terminal of the fourth N-type transistor, and a gate terminal of the seventh N-type transistor receives the enable signal, and the seventh N-type transistor is turned on when the enable signal is activated.

16. The level shifter as claimed in claim 11, further comprising:
a sixth N-type transistor, wherein the drain terminal of the third N-type transistor is coupled to the third node through the sixth N-type transistor; and
a seventh N-type transistor, wherein the drain terminal of the fourth N-type transistor is coupled to the fourth node through the seventh N-type transistor,
wherein a drain terminal of the sixth N-type transistor is connected to the drain terminal of the third P-type transistor, a source terminal of the sixth N-type transistor is connected to the third node, and a gate terminal of the sixth N-type transistor receives the enable signal, and the sixth N-type transistor is turned on when the enable signal is activated,
wherein a drain terminal of the seventh N-type transistor is connected to the drain terminal of the fourth P-type transistor, a source terminal of the seventh N-type transistor is connected to the fourth node, and a gate terminal of the seventh N-type transistor receives the enable signal, and the seventh N-type transistor is turned on when the enable signal is activated.

17. The level shifter as claimed in claim 10, further comprising:
a fifth P-type transistor, wherein the drain terminal of the first P-type transistor is coupled to the first node through the fifth P-type transistor; and
a sixth P-type transistor, wherein the drain terminal of the second P-type transistor is coupled to the second node through the sixth P-type transistor,
wherein a source terminal of the fifth P-type transistor is connected to the drain terminal of the first P-type transistor, a drain terminal of the fifth P-type transistor is connected to the first node, and a gate terminal of the fifth P-type transistor receives the inverted enable signal, and the fifth P-type transistor is turned on when the enable signal is activated,
wherein a source terminal of the sixth P-type transistor is connected to the drain terminal of the second P-type transistor, a drain terminal of the sixth P-type transistor is connected to the second node, and a gate terminal of the sixth P-type transistor receives the inverted enable signal, and the sixth P-type transistor is turned on when the enable signal is activated.
